(19) United States
(12) Patent Application Publication
(10) Pub. No.: US 2011/0307752 A1
(43) Pub. Date: Dec. 15, 2011

(54) SEMICONDUCTOR DEVICE, AND DESIGN METHOD, DESIGN TOOL, AND FAULT DETECTION METHOD OF SEMICONDUCTOR DEVICE

(75) Inventors: Naohiro Fujil, Osaka (JP); Kinya Daio, Kyoto (JP); Shinichi Yoshimura, Kyoto (JP)

(73) Assignee: PANASONIC CORPORATION, Osaka (JP)

(21) Appl. No.: 13/218,207

(22) Filed: Aug. 25, 2011

Related U.S. Application Data
(63) Continuation of application No. PCT/JP2009/004860, filed on Sep. 25, 2009.

(30) Foreign Application Priority Data
Feb. 26, 2009 (JP) 2009-044095

(51) Int. Cl. G01R 31/3177; G06F 17/50; G06F 11/25

(52) U.S. Cl. 714/731; 716/102; 714/E11.155

(57) ABSTRACT

A bridging fault which has occurred between clock signal lines in a semiconductor device can be easily detected. A semiconductor device having a plurality of hold circuits and configured such that a scan test can be performed includes a first and a second clock signal lines supplied with normal operational clock signals having at least either frequencies or phases different from each other during normal operation, and a test clock signal controller which switches, during a test, between a state in which a first test clock signal, which is the same as that supplied to the first clock signal line, is supplied to the second clock signal line, and a state in which a second test clock signal, which is inverted or phase-shifted relative to the first test clock signal, is supplied to the second clock signal line.

### CROSS-REFERENCE TO RELATED APPLICATION

This is a continuation of PCT International Application PCT/JP2009/004860 filed on Sep. 25, 2009, which claims priority to Japanese Patent Application No. 2009-044095 filed on Feb. 26, 2009. The disclosures of these applications including the specifications, the drawings, and the claims are hereby incorporated by reference in its entirety.

### BACKGROUND

The present invention relates to semiconductor devices such as scaled complementary metal oxide semiconductor (CMOS) integrated circuits, and more particularly to semiconductor devices configured such that a scan test can be performed.

In recent years, reduction in feature sizes in CMOS integrated circuits has progressed, and the gate sizes of CMOS integrated circuits have been increasing. Effective techniques for testing a CMOS integrated circuit having a large gate size include a scan test technique.

Specific features of a scan test include the capability to easily provide any internal logic gate with any value (high controllability), and the capability to easily observe the status of any internal logic gate (high observability).

These features allow a high quality test to be easily performed by performing a scan test.

In addition, utilizing these features, not only a scan test, but also various scan test-based test techniques have been developed, including an IDDQ test using a scan circuit (which utilizes the controllability of internal logic circuits), a burn-in test using a scan circuit (which utilizes the controllability of internal logic circuits), and a scan circuit-based BIST (self-diagnostic test).

Here, the number of clock signals for driving each flip-flop circuit in an integrated circuit during normal operation of the integrated circuit is not necessarily limited to one, but clock signals having various frequencies and/or phases may be used. In particular, a large scale CMOS integrated circuit etc. manufactured using a recent miniaturization technology may include as many as hundreds of clock systems. In such a case, the clock signals supplied to each flip-flop circuit are, for example, directed to one clock system by switching in selectors during a scan test (see, e.g., Japanese Patent Publication No. H10-307167).

### SUMMARY

However, if clock signals of more than one systems are directed to one clock system etc. as described above, then even when a bridging fault occurs, in which a short circuit occurs between clock signal lines which transmit clock signals different from each other during normal operation, a scan test completes successfully. Thus, a problem exists in that a bridging fault between clock signal lines themselves cannot be detected.

The present invention has been made in view of the foregoing, and it is an object of the present invention to enable a semiconductor device, configured such that a scan test can be performed, to easily detect a bridging fault which has occurred between clock signal lines which transmit clock signals different from each other during normal operation.

In order to solve the problem, a semiconductor device according to an example of the present invention is a semiconductor device having a plurality of hold circuits and configured such that a scan test can be performed, including:

a first and a second clock signal lines supplied with normal operational clock signals having at least either frequencies or phases different from each other during normal operation, and

a test clock signal controller configured to switch, during a test, between a state in which a first test clock signal, which is the same as that supplied to the first clock signal line, is supplied to the second clock signal line, and a state in which a second test clock signal, which is inverted or phase-shifted relative to the first test clock signal, is supplied to the second clock signal line.

Thus, a bridging fault occurring between the first and the second clock signal lines can be detected upon a scan test or an IDDQ test as a failure of the test.

According to the present invention, a semiconductor device, configured such that a scan test can be performed, can easily detect a bridging fault occurring between clock signal lines which transmit clock signals different from each other during normal operation.

### BRIEF DESCRIPTION OF THE DRAWINGS

FIG. 1 is a circuit diagram of a main portion of a semiconductor device of a first embodiment.

FIG. 2 is a timing diagram illustrating an operation during a scan test on the semiconductor device of the first embodiment.

FIG. 3 is a timing diagram illustrating an operation during an IDDQ test on the semiconductor device of the first embodiment.

FIG. 4 is a circuit diagram of a main portion of a semiconductor device of a variation of the first embodiment.

FIG. 5 is a circuit diagram of a main portion of a semiconductor device of a second embodiment.

FIG. 6 is a timing diagram illustrating an operation during a test on the semiconductor device of the second embodiment.

FIG. 7 is a circuit diagram of a main portion of a semiconductor device of a first variation of the second embodiment.

FIG. 8 is a circuit diagram of a main portion of a semiconductor device of a second variation of the second embodiment.

FIG. 9 is a circuit diagram of a main portion of a semiconductor device of a third variation of the second embodiment.

FIG. 10 is a circuit diagram of a main portion of a semiconductor device of a fourth variation of the second embodiment.

FIG. 11 is a circuit diagram of a main portion of a semiconductor device of a fifth variation of the second embodiment.

FIG. 12 is a circuit diagram of a main portion of a semiconductor device of a third embodiment.

FIG. 13 is a timing diagram illustrating an operation during a test on the semiconductor device of the third embodiment.

FIG. 14 is a circuit diagram of a main portion of a semiconductor device of a first variation of the third embodiment.

FIG. 15 is a circuit diagram of a main portion of a semiconductor device of a second variation of the third embodiment.

FIG. 16 is a circuit diagram of a main portion of a semiconductor device of a third variation of the third embodiment.

FIG. 17 is a circuit diagram of a main portion of a semiconductor device of a fourth variation of the third embodiment.

FIG. 18 is a circuit diagram of a main portion of a semiconductor device of a fifth variation of the third embodiment.

FIG. 19 is a circuit diagram of a main portion of a semiconductor device of a fifth embodiment.

FIG. 20 is a circuit diagram of a main portion of a semiconductor device of a variation of the fifth embodiment.

FIG. 21 is a flowchart illustrating an example of a designing step of a sixth embodiment.

FIG. 22 is a flowchart illustrating another example of a designing step of the sixth embodiment.

FIG. 23 is a circuit diagram of a main portion of a semiconductor device of a seventh embodiment.

### DETAILED DESCRIPTION

Example embodiments of the present invention will be described below in detail with reference to the drawings. In each embodiment, the same reference numerals are used to represent elements having similar functions to those of other embodiments, and the explanation thereof will be omitted.

First Embodiment of Invention

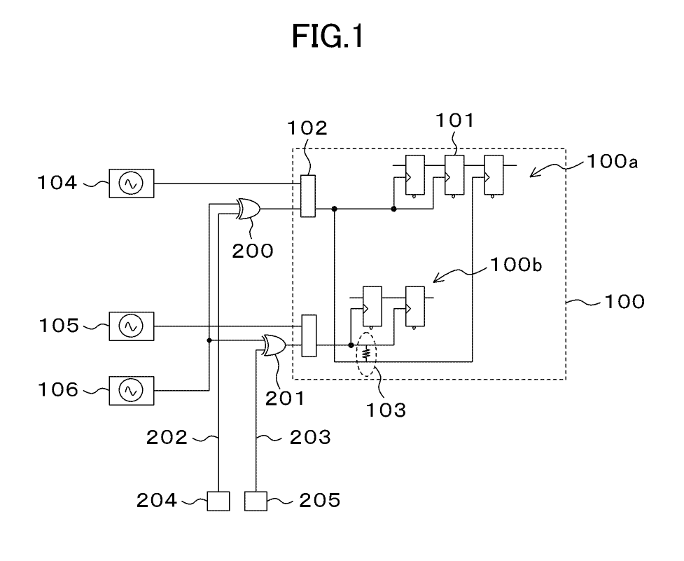

FIG. 1 is a circuit diagram of a portion including a scan circuit 100, associated with a scan test, of a semiconductor device of a first embodiment. FIG. 1 illustrates that two scan paths 100a and 100b are formed during a scan test etc. by a plurality of flip-flop circuits 101 provided in the semiconductor device.

The flip-flop circuits 101 forming the scan paths 100a and 100b are supplied with clock signals 104 and 105 during normal operation of the semiconductor device, and with a scan clock signal 106 during a scan test through exclusive OR (XOR) circuits 200 and 201, by selections of selectors 102.

The XOR circuits 200 and 201 each function as a clock signal controller for bridge detection. For example, if control signals 202 and 203 respectively input to control signal terminals 204 and 205 from a fault detection unit etc. of the semiconductor device are each at Low level (“L”), then the XOR circuits 200 and 201 directly output the scan clock signal 106. Meanwhile, if the control signals 202 and 203 are each at a High level (“H”), then the XOR circuits 200 and 201 each output an inverted scan clock signal, which is obtained by inverting (applying a phase shift of 180° to) the scan clock signal 106.

A bridging fault between the clock signal lines in the semiconductor device configured as described above can be detected simultaneously with a scan test, or with detection of a fault of another signal line or circuit by an IDDQ test.

That is, for example, in a scan test, inducing a shift operation in the scan paths 100a and 100b in synchronism with the clock signal causes test data to be set in the flip-flop circuits 101, and a signal status captured by a subsequent capture operation in the semiconductor device to be read. Then, the signal status read is compared with an expected value, and thus whether the semiconductor device has normally operated or not is examined.

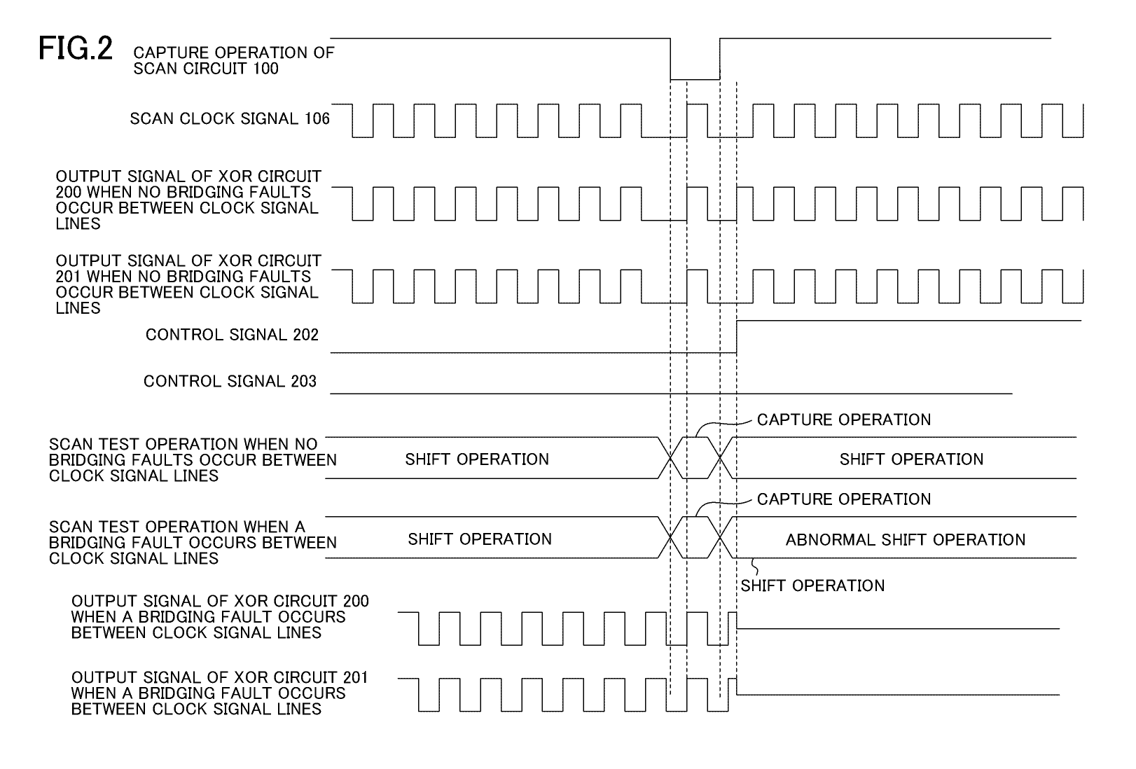

When such a shift operation is induced, driving “H” only either the control signal 202 or 203 -- by way of example, only the control signal 202 -- causes a clock signal output from the XOR circuit 200 to be inverted as shown in FIG. 2, and thus clock signals output from the XOR circuits 200 and 201 have opposite levels with respect to each other. Even in such a case, as long as no bridging fault occurs between the clock signal lines, the shift operations themselves of the scan paths 100a and 100b are normally performed, except that one is shifted by half the clock period. Accordingly, the captured signal status is read and compared with the expected value, and thus it is determined whether the circuit operation has been normally performed or not.

However, if, for example, a bridging fault 103 between clock signal lines occurs as shown in FIG. 1, the potentials of the clock signal lines interfere with each other, and thereby causing the both potentials to become, for example, the center potential. In this case, the shift operation is not normally performed, and thus even if the circuit operates normally and the captured signal status is normal, the signal status read does not match the expected value.

Thus, if the signal status read matches the expected value, it can be determined that the circuit has operated normally and no bridging fault between the clock signal lines has occurred; meanwhile, if the signal status read does not match the expected value, then it can at least be detected either that the circuit has not operated normally upon capturing, or that a bridging fault has occurred between the clock signal lines. Moreover, if a scan test is passed when the control signals 202 and 203 are both driven “H” or “L,” and a scan test is failed when only one of the control signals is driven “H,” then it can be detected that only a bridging fault has occurred.

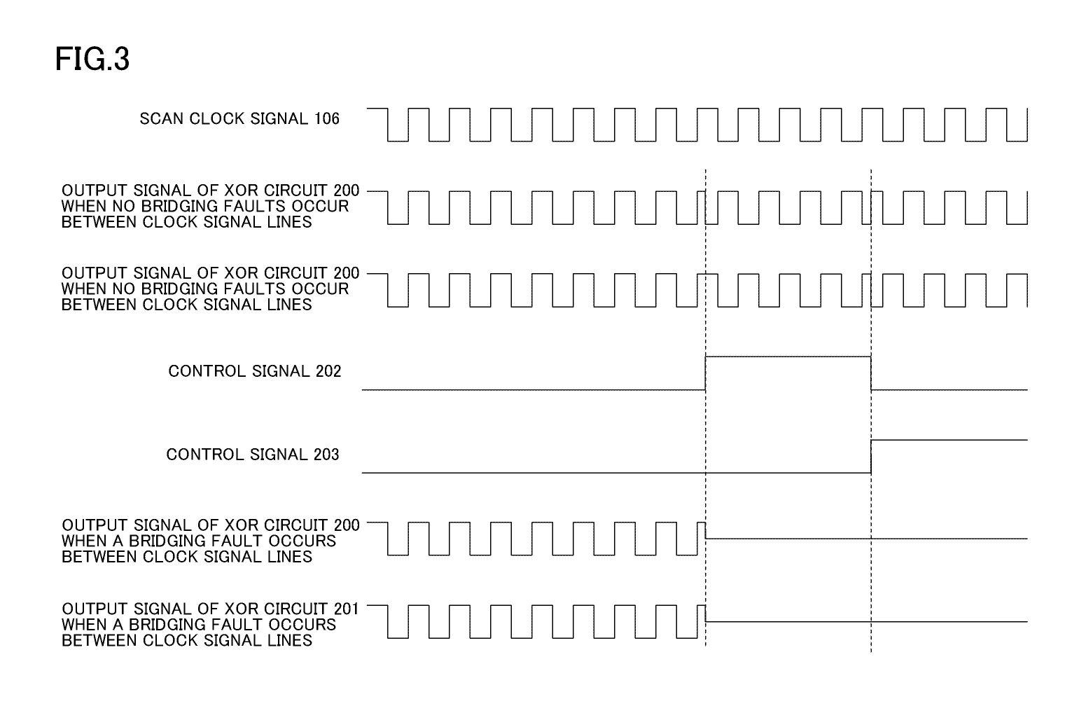

An IDDQ test may be performed under a condition in which the clock signal is not completely stopped, but a clock signal having a sufficiently low frequency is supplied. Also in such a case, driving “H” only one of the control signals 202 and 203 as shown in FIG. 3 allows a bridging fault between the clock signal lines to be detected, along with other faults, as a result of an IDDQ test. That is, if a bridging fault has occurred between the clock signal lines, the potentials of the clock signal lines interfere with each other, and thus a short-circuit current flows through the clock signal lines themselves. In addition, the potentials of the both clock signal lines become, for example, the center potential. If this center potential is applied to the flip-flop circuits 101, a pass-through current flows through the flip-flop circuits 101. Thus, monitoring the power supply current allows the semiconductor device to detect at least either that a bridging fault has occurred between lines including the clock signal lines, or that a circuit fault point exists etc. Note that, if the power supply current is higher when only one of the control signals 202 and 203 is driven “H” than when the control signals are both driven “H” or “L,” then it can also be detected that it is highly likely that a bridging fault has occurred.

As described above, supplying a clock signal with a phase shift allows a failure of the semiconductor device to be detected, including a bridging fault between the clock signal lines, by performing a scan test or an IDDQ test. Note that, aside from a scan test and an IDDQ test, there is a method for detecting only a bridging fault between the clock signal lines. More specifically, for example, the semiconductor device may perform only a shift operation similar to a scan test, and monitor whether input data is output without any change, etc. In addition, it is also advantageous to monitor the operating power-supply current during a shift operation of a scan test.

Variation

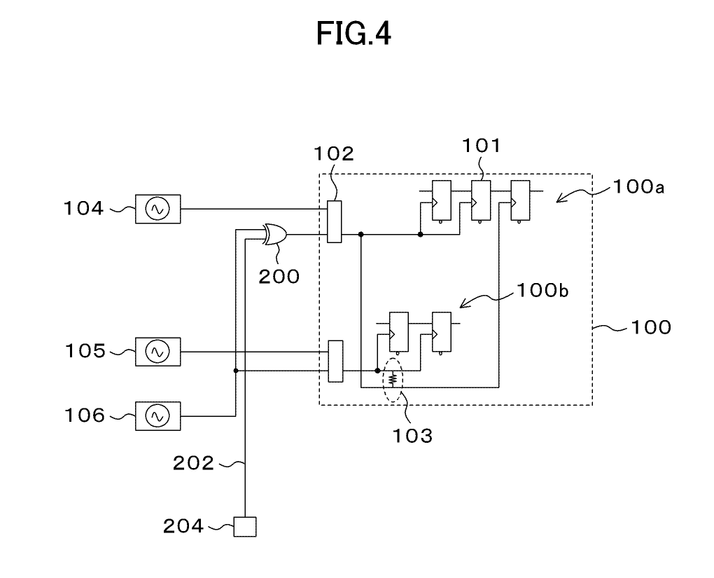

Although the above example assumes that the XOR circuits 200 and 201 are provided on the clock signal lines of the respective scan paths 100a and 100b, for example, an XOR circuit may be provided only on one of the clock signal lines as shown in FIG. 4 to fix the scan path to which the inverted clock signal can be supplied. In addition, although the above example assumes that the two scan paths 100a and 100b are provided for simplicity of explanation, three or more scan paths may be provided. Also in such a case, an XOR circuit may be provided on each of the clock signal lines to allow any of the scan clock signals 106 to be inverted, or XOR circuits may be provided only on some of the clock signal lines. That is, providing XOR circuits on all the clock signal lines or on all but one of the clock signal lines allows a bridging fault between any pair of clock signal lines to be independently detected. Moreover, as will be described below, providing XOR circuits on a part of the clock signal lines based on a prediction of a likelihood of occurrence of a fault etc. also allows a practically sufficient examination to be performed.

Furthermore, although the above example has been described in which the XOR circuits 200 and 201 are used to shift the phase of a clock signal, the implementation is not limited thereto, but, for example, a combination of NOT circuits, flip-flop circuits, or delay elements and selectors may be used. The amount of phase shift does not necessarily need to be 180°.

Although the above example has been described in which a phase shift is applied after the capture operation in a scan test, the phase shift may also be applied, in order to detect a bridging fault, before the capture operation, only in a limited time period before or after the capture operation, or over a relatively long time period before and after the capture operation to further increase the detection probability. However, if the phase shift is applied when test data is set before the capture operation, and the capture operation is performed immediately after the test data setting in synchronism with the undelayed one of the scan clock signals, the flip-flop circuits included in the scan path corresponding to the delayed one of the scan clock signals may fail to properly hold an input signal because the setup time is half a period of the scan clock signal. In such a case, it is preferable, for example, that the frequency of the scan clock signal be reduced (e.g., to half the frequency) so that a same setup time is ensured as when the scan clock signal is not delayed, or that the time period from a completion of test data setting to the capture operation be set so that the restrictions on setup of the flip-flop circuits are satisfied. Note that, if the phase shift is applied only after the capture operation, only the timing of outputting the signal status captured from the scan path is shifted, and thus the problem of the restrictions on setup as described above does not occur.

Although the above example assumes that the XOR circuits 200 and 201 are provided in the input sides of the selectors 102, the XOR circuits 200 and 201 may be provided in the output sides of the selectors 102. That is, even if the XOR circuits 200 and 201 are provided in the output sides, as long as the clock signals 104 and 105 which are not inverted are always output during normal operation, the normal operation is not adversely affected in general. Strictly speaking, delays due to the XOR circuits 200 and 201 are introduced regardless of whether provided before or after the selectors 102, and therefore it is preferable that delay adjustment be performed on the clock signals with respect to skew etc. including such delays. In other words, the XOR circuits 200 and 201 can also be each used as a delay element in delay adjustment for adjusting a signal transmission delay in a predetermined section within a predetermined range. That is, this configuration is useful for reducing the number of gates for timing adjustment formed by buffers etc.

Second Embodiment of Invention

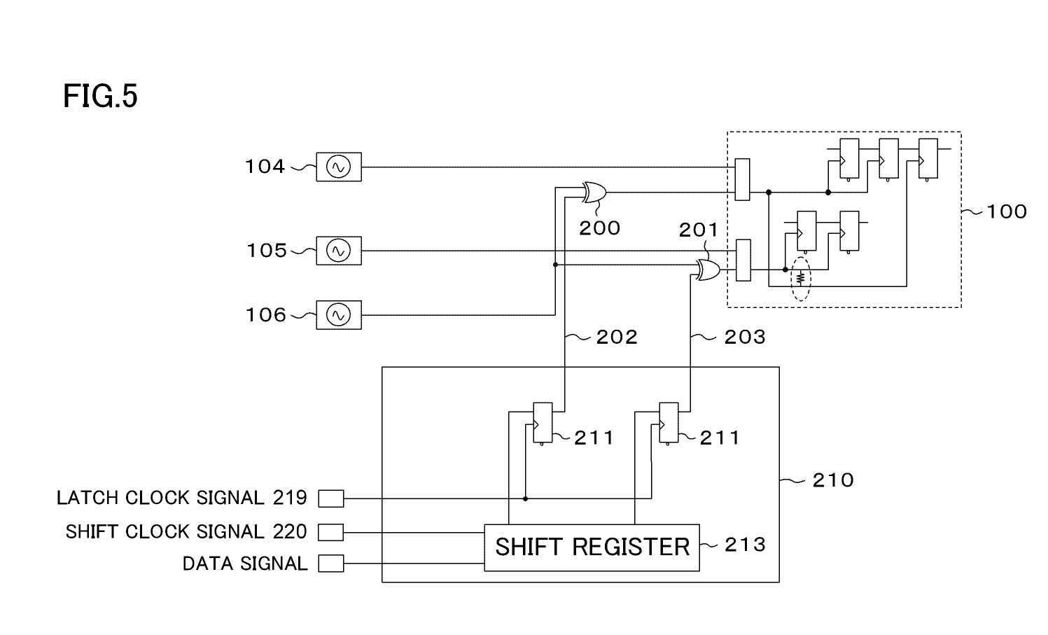

In general, a large number of XOR circuits are provided which invert scan clock signals as described above. Thus, control signals for controlling these XOR circuits may be generated by a control signal generator 210 such as one shown in FIG. 5 to allow the number of terminals of the semiconductor device to be reduced.

More specifically, the control signal generator 210 includes, for example, control signal hold circuits 211 and a shift register 213. The shift register 213 receives input data when a data signal is input thereto in synchronism with a shift clock signal 220. The control signal hold circuits 211 each hold an output signal of the shift register 213 in synchronism with a latch clock signal 219.

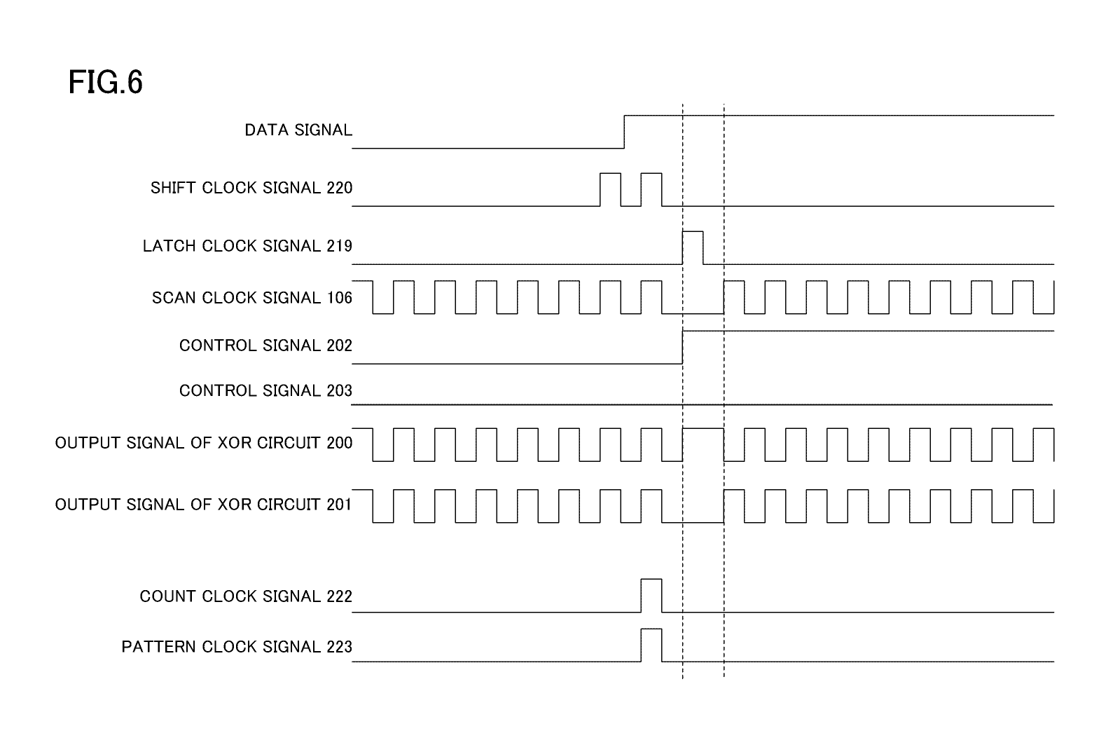

With such a configuration, as shown in FIG. 6 for example, when a data signal is input in synchronism with a two-clock shift clock signal 220, the shift register 213 receives the input data. Next, when the latch clock signal 219 goes “H,” the output of the shift register 213 is held in the control signal hold circuits 211, and by way of example, only the control signal 202 goes “H,” thereby causing the scan clock signal 106 output from the XOR circuit 200 to be inverted.

Thus, a one-bit data signal allows a setting operation of as many control signals as the number of pulses of the shift clock signal 220. Accordingly, even when a large number of scan paths exist, the number of terminals of the semiconductor device can be reduced to a low value.

Note that the example of FIG. 6 illustrates that the scan clock signal 106 remains “L” for a time period of one clock when the latch clock signal 219 goes “H.” Although this operation is generally preferable in that short duration pulses are easily prevented from being output from the XOR circuits 200 and 201, the operation is not limited thereto.

In addition, although FIG. 6 shows that no capture operation is performed when the scan clock signal 106 is inverted, a capture operation may be performed similarly to the case shown in FIG. 2. In such a case, the latch clock signal 219 may go “H” after the capture operation, and the scan clock signal 106 may be inverted at a timing similar to that of FIG. 2.

Moreover, the shift clock signal 220 may be stopped after predetermined data is set in the shift register 213, and thus the signals held in the shift register 213 may be directly used as the control signals 202 and 203 etc. However, if any variation in the control signals 202 and 203 during a shift operation of the data signal needs to be reduced, or if the timing when the scan clock signal 106 is inverted needs to be controlled, then the output signals of the shift register 213 may be passed through AND gates to generate the control signals 202 and 203.

First Variation

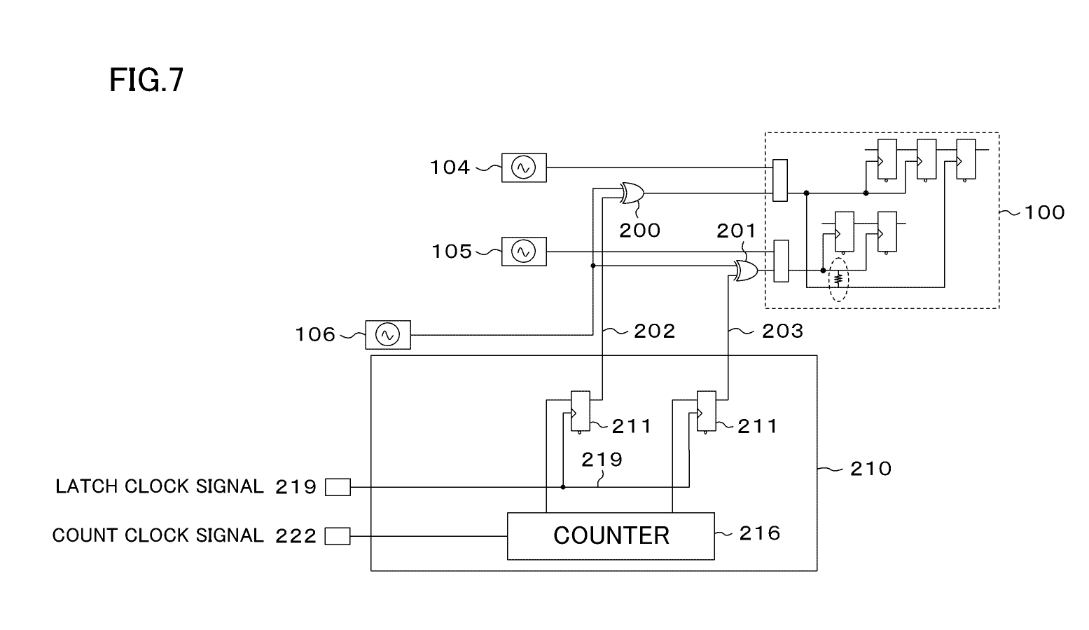

A counter 216 as shown in FIG. 7 may be used in place of the shift register 213. In this case, there is no need to input a data signal; but, as shown together in FIG. 6, the pattern of the control signals 202 and 203 can be set by driving the latch clock signal 219 “H” when the number of pulses of a count clock signal 222 input to the counter 216 reaches a desired number (“1” in the example of FIG. 6).

Second Variation

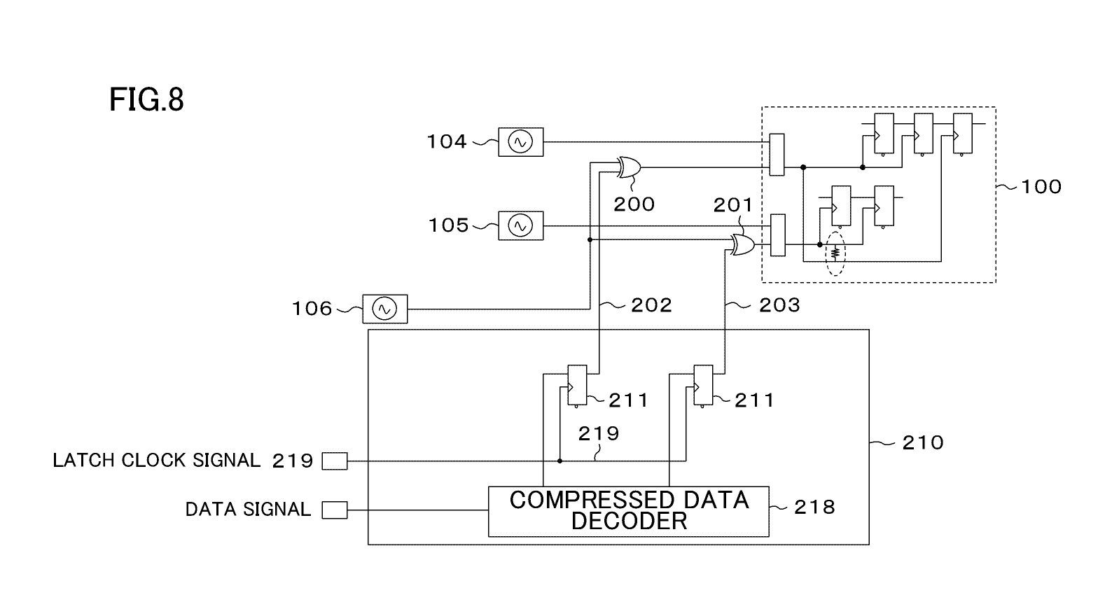

As shown in FIG. 8, a compressed data decoder 218, which receives a compressed data signal, may be provided to allow a larger number of patterns of the control signals 202 and 203 to be set than the number of bits of the data signal. In such a configuration, if the patterns of the control signals 202 and 203 are limited -- more specifically, for example, if only two patterns (the both are “L” and only one is “H”) need to be set among the four combinations of “H” and “L” of the control signals 202 and 203, then the number of bits of the data signal can be reduced to one. In addition, usage of compressed data allows the time required to input (transfer) the data signal to be reduced.

Third Variation

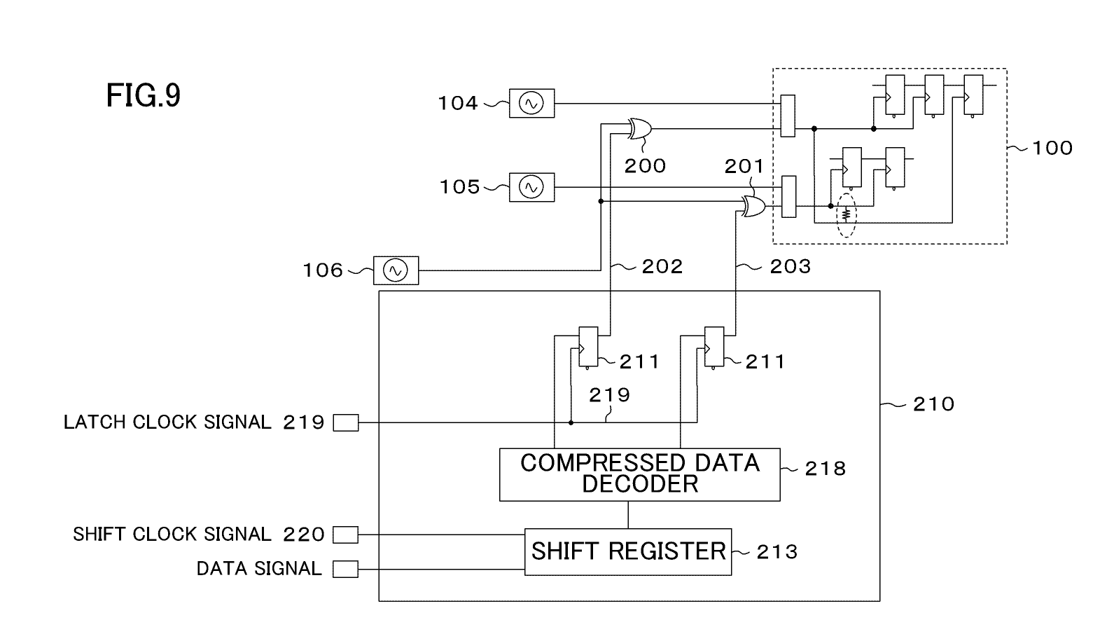

As shown in FIG. 9, the shift register 213 of the second embodiment (FIG. 5) and the compressed data decoder 218 of the aforementioned second variation (FIG. 8) may be used in combination so as to decode the compressed data held in the shift register 213 in synchronism with the shift clock signal 220, and to set the control signals 202 and 203. In this case, a larger number of patterns of the control signals 202 and 203 can be set than the number of bits of the data signal transferred to the shift register 213, and thus the number of stages of the shift register 213 can be reduced, and the transfer time of the data signal can also be reduced.

Fourth Variation

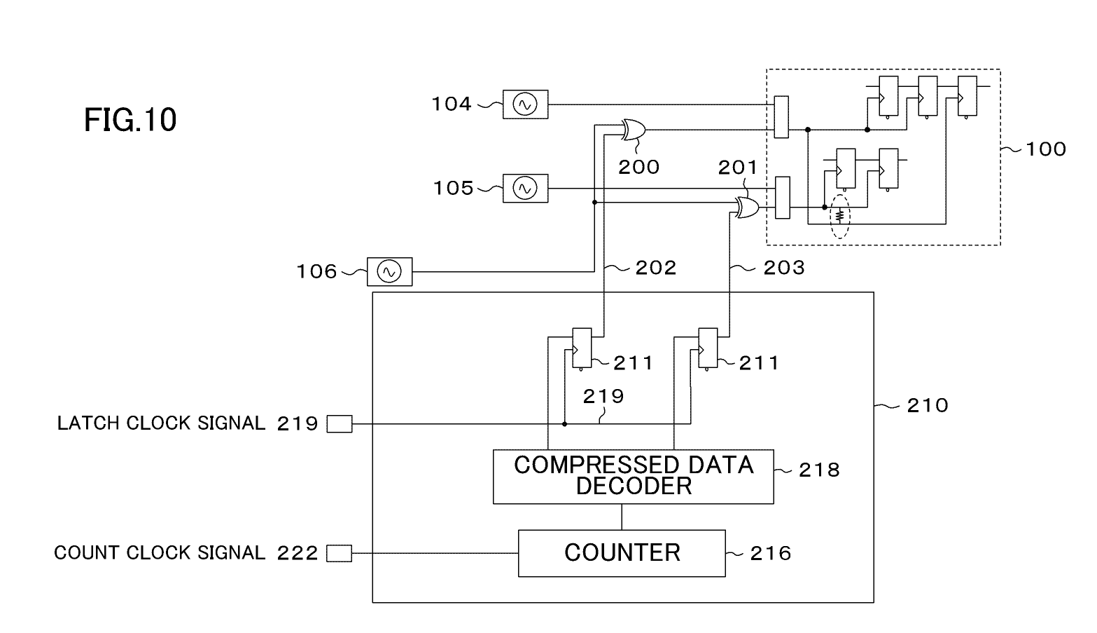

As shown in FIG. 10, the counter 216 of the aforementioned first variation (FIG. 7) and the compressed data decoder 218 of the aforementioned second variation (FIG. 8) may be used in combination so as to decode the count value held in the counter 216, and to set the control signals 202 and 203. In this case, as many patterns of the control signals 202 and 203 as a number dependent on the count value of the counter 216 can be set, and thus the number of pulses of the count clock signal 222 input to the counter 216 can be reduced, and the setting time can also be reduced.

Fifth Variation

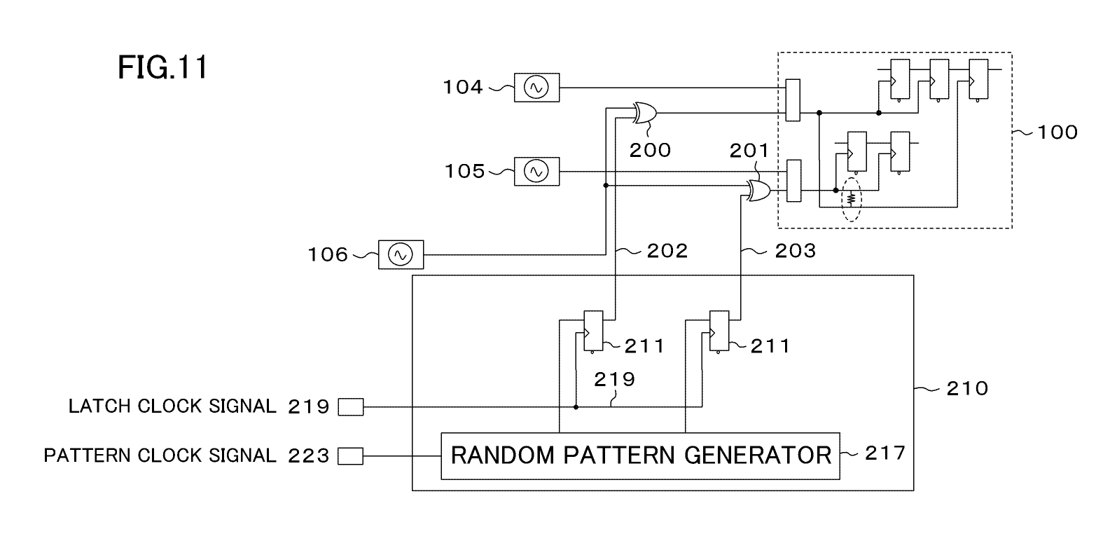

As shown in FIG. 11, a random pattern generator 217 may be used. The random pattern generator 217 includes, for example, a circuit etc., such as a CRC circuit, which can be expressed by a generator polynomial. The random pattern generator 217 outputs random data each time a pulse of a pattern clock signal 223 is input. Thus, as shown together in FIG. 6, the control signals 202 and 203 can be set at random by driving the latch clock signal 219 “H” after the pattern clock signal 223 goes “H.” Passing scan tests etc. repeatedly performed according to the control signals 202 and 203 based on such random patterns can show that a bridging fault is very unlikely to have occurred between the clock signal lines.

Third Embodiment of Invention

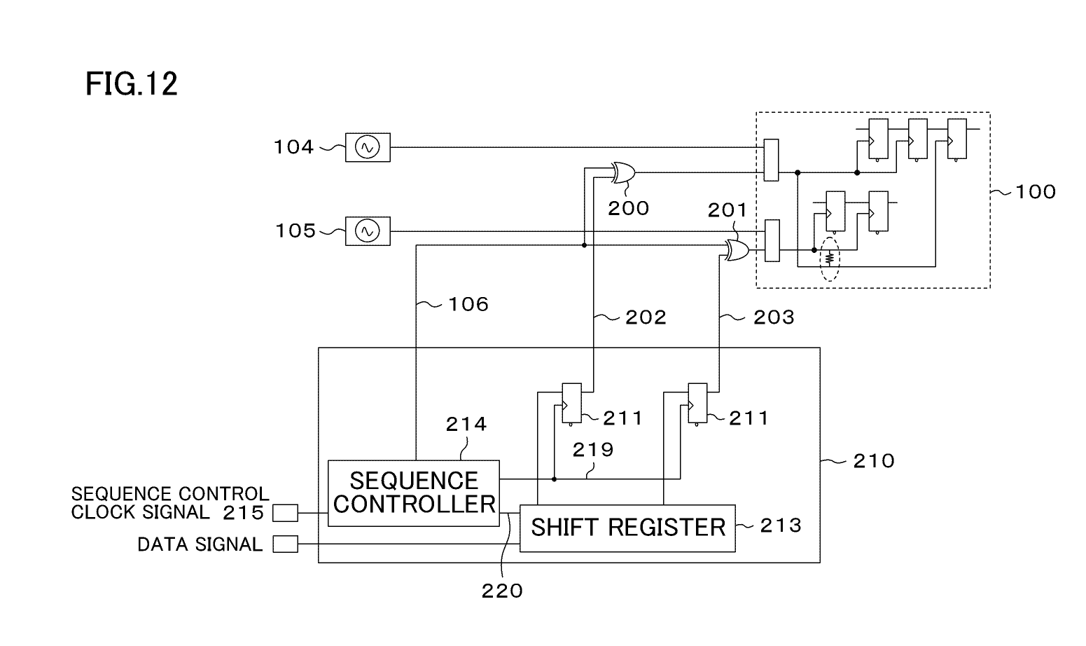

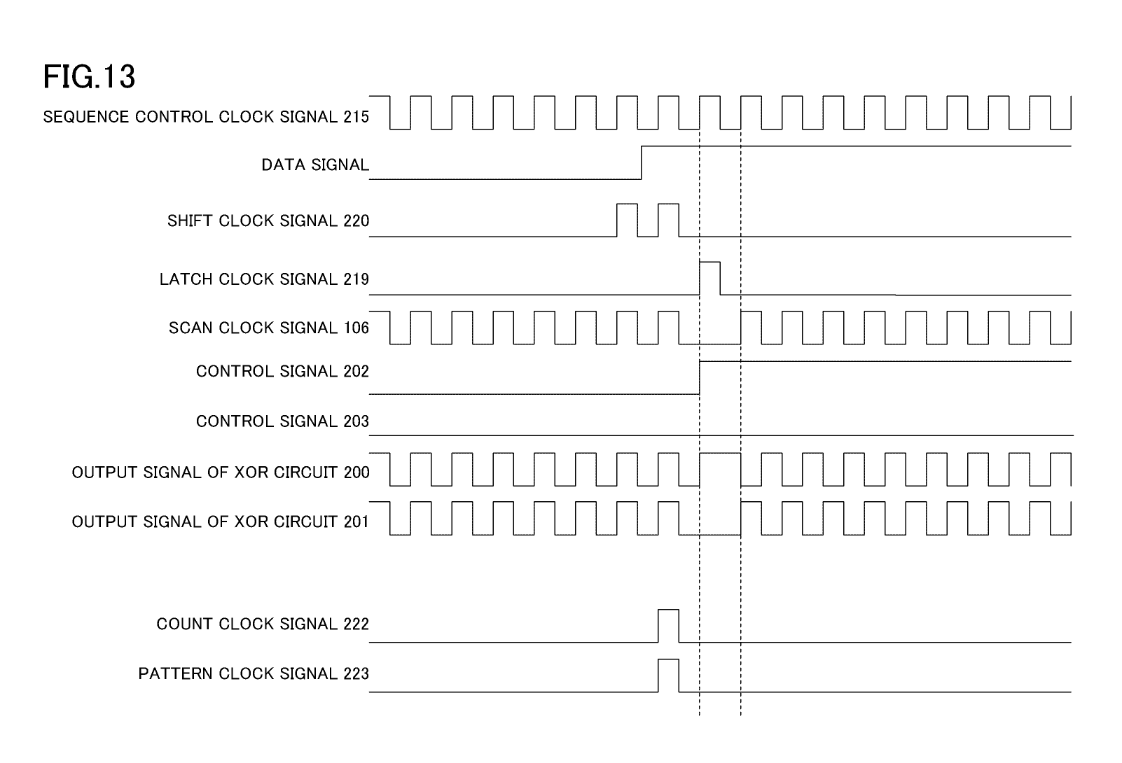

As shown in FIG. 12, a sequence controller 214 may be provided in addition to the configuration of the second embodiment, and may generate the shift clock signal 220 etc. based on a sequence clock signal 215. More specifically, for example, the sequence controller 214 includes a counter and a decoder, counts the number of pulses of the sequence clock signal 215, and outputs, as shown in FIG. 13, the shift clock signal 220, the latch clock signal 219, and the scan clock signal 106 depending on the count value at a timing similar to that of FIG. 6.

Thus, only inputting the sequence clock signal 215 and a data signal allows a same operation as that of the second embodiment (FIGS. 5 and 6) to be performed, and therefore further reduction in the number of terminals of the semiconductor device and easier examinations can be expected.

First through Fifth Variations

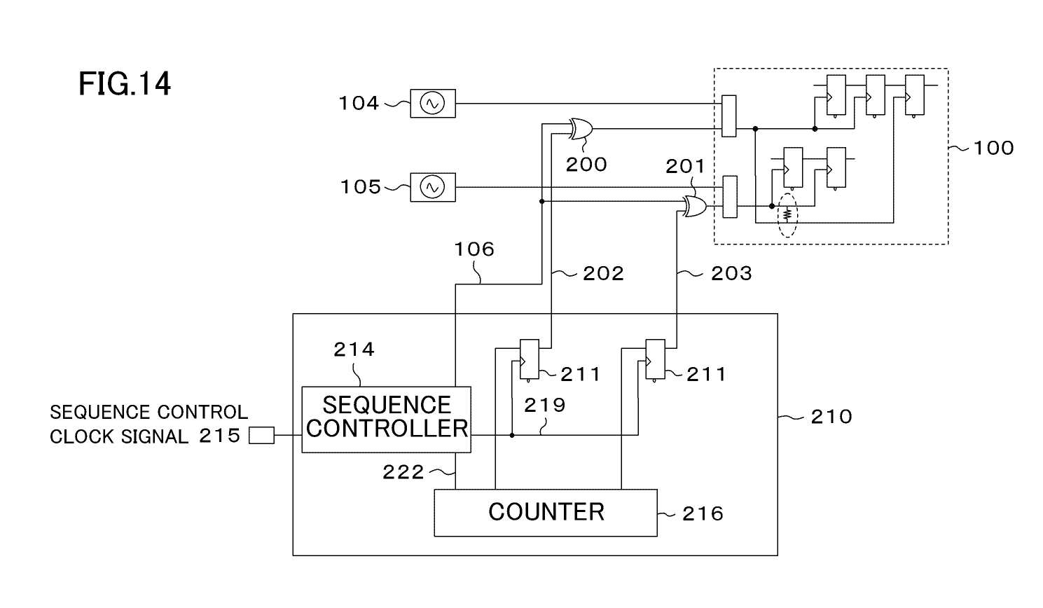

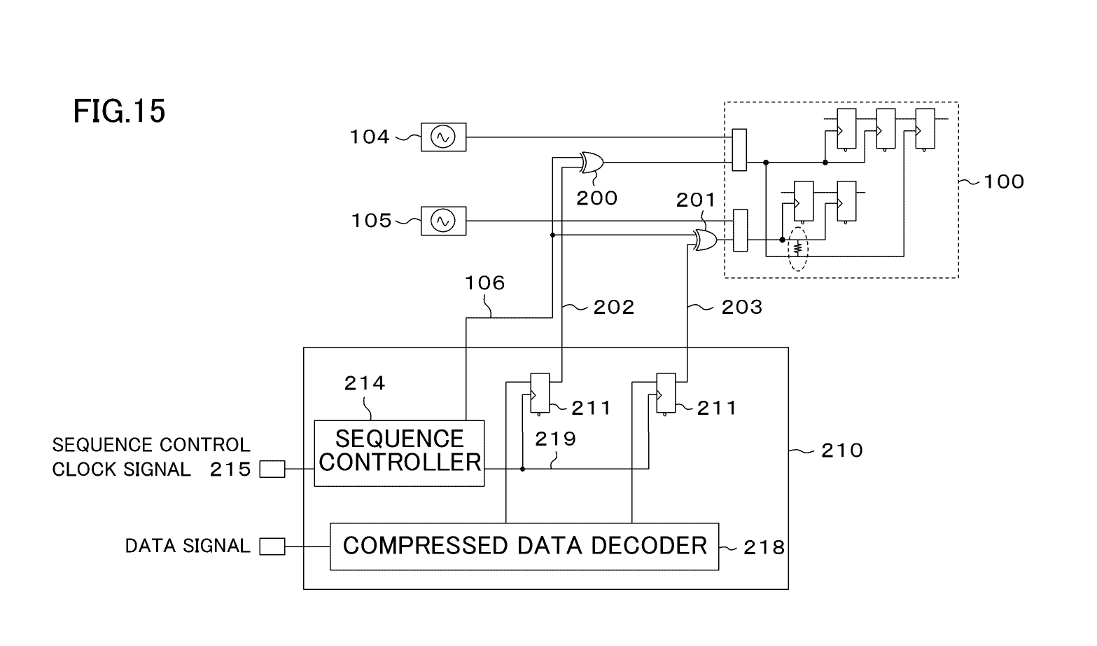

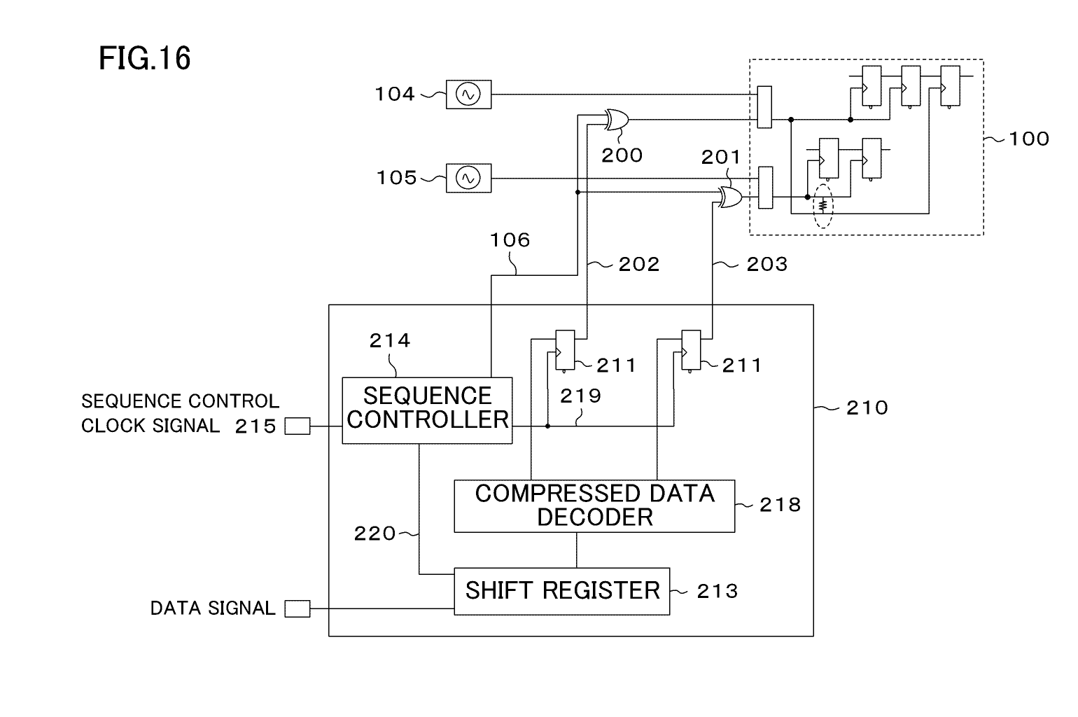

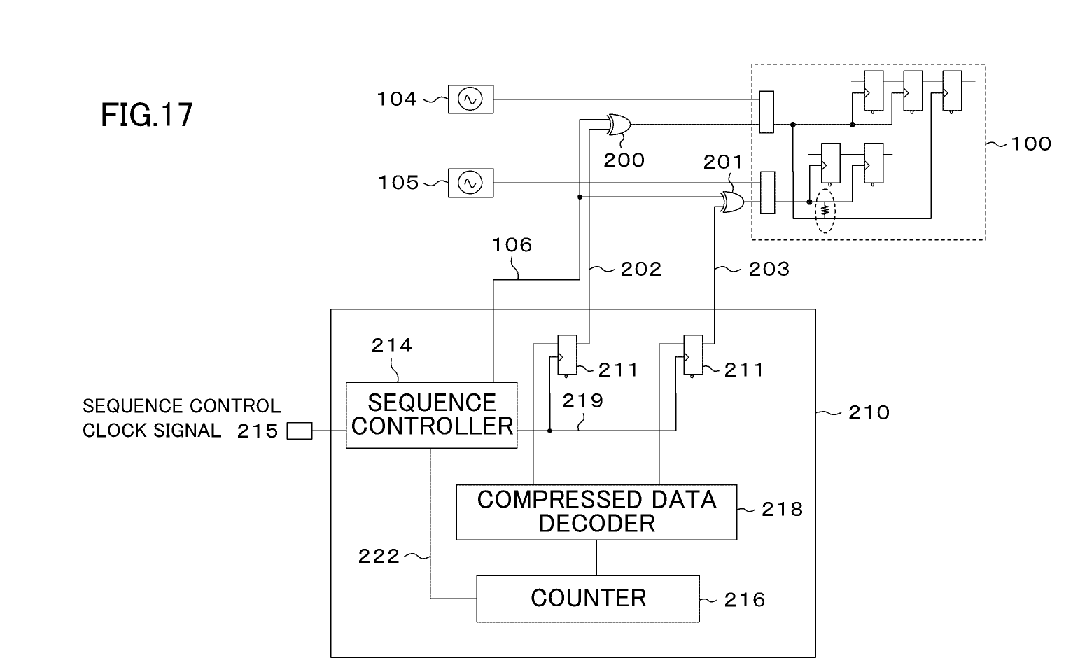

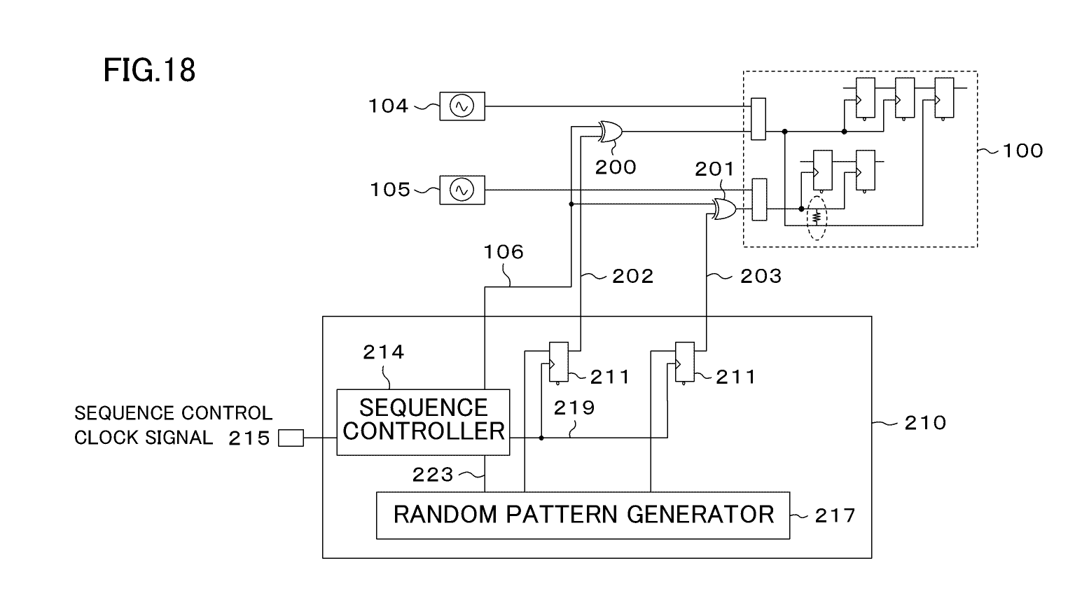

Similarly, as shown in FIGS. 14-18, the sequence controller 214 may be provided in addition to the respective configurations of the first through the fifth variations of the second embodiment. As shown together in FIG. 13, the sequence controller 214 may generate the count clock signal 222, the latch clock signal 219, the scan clock signal 106, the shift clock signal 220, and the pattern clock signal 223 also at a timing similar to that of FIG. 6 in order to reduce the number of terminals of the semiconductor device, and to achieve easier examinations.

Fourth Embodiment of Invention

Setting patterns for setting the control signals 202 etc. to “H” or “L” in the above second and third embodiments will now be discussed.

The above examples each show an example of two clock systems for simplicity of explanation. If there are a large number of clock systems, and the bridging fault point needs to be located by fault analysis, it is preferable that a setting pattern be used which drives the control signals “H” or “L” one by one, sequentially.

Meanwhile, if there is no need to locate the bridging fault point, and only whether a fault exists or not needs to be detected, then, for example, an appropriate setting of a combination of control signals driven “H” and control signals driven “L” allows the number of setting patterns to be reduced, and also allows the examination time to be easily reduced.

Fifth Embodiment of Invention

(Installation Locations of XOR Circuits 200 etc.)

The XOR circuits 200 etc. for inverting the scan clock signal 106, and the control signal hold circuits 211 for holding the control signals 202 etc. (or control signal terminals 204 etc.) do not necessarily need to be provided on all the clock signal lines which are supplied with the clock signals 104, 105, 111, and 112 having frequencies and/or phases different from one another during normal operation. That is, a bridging fault is more likely to occur at a point where clock signal lines intersect each other or are adjacent to each other, or in a portion where clock signal lines extend in parallel with each other over a relatively long distance, and thus obtaining or predicting such points, and providing the XOR circuits 200 etc. mainly on the clock signal lines having such points allows the circuit size to be reduced, and also allows the examination time to be easily reduced.

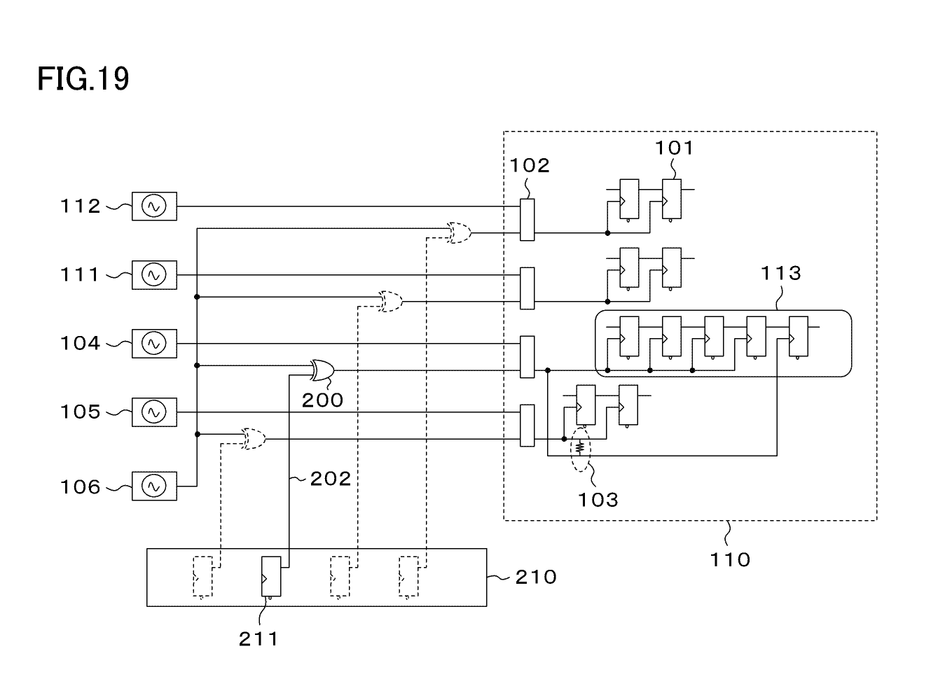

More specifically, for example, if a clock system includes more (five) flip-flop circuits 101 than the other clock systems (two for each) such as a clock system 113 shown in FIG. 19, the clock signal line of the clock system 113 is often longer than the others, and thus it can be inferred that it is more likely that the bridging fault 103 may occur between that clock signal line and another clock signal line. Accordingly, the bridging fault 103 can be detected with a high probability even if the XOR circuit 200, the control signal hold circuit 211, and the control signal 202 are provided only for the clock signal line which supplies the scan clock signal 106 to the clock system 113, and no such elements are provided on the other clock signal lines as shown by dotted lines in FIG. 19.

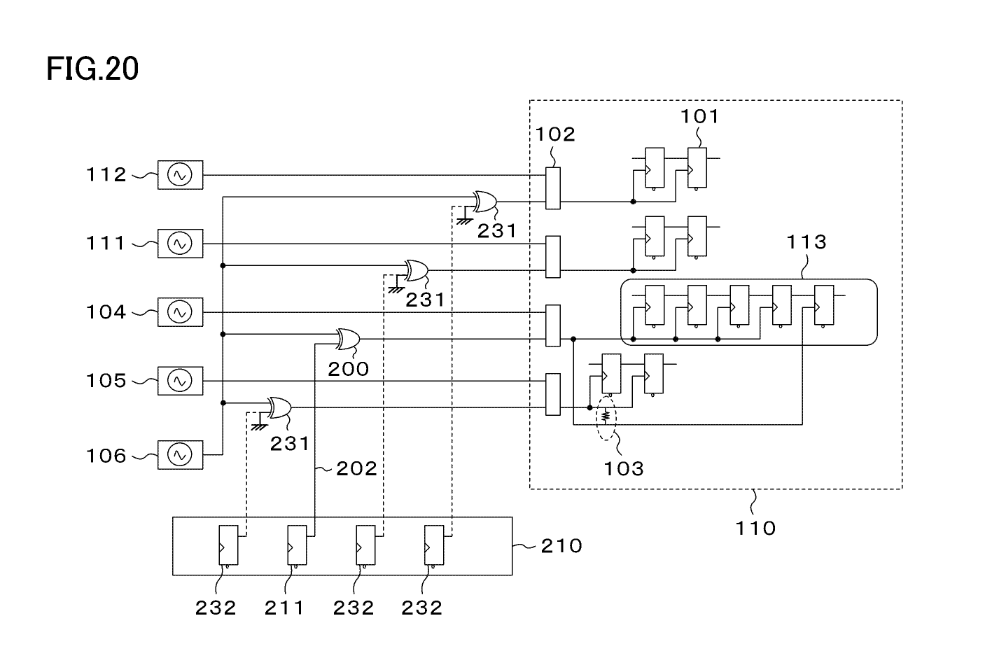

Meanwhile, as shown in FIG. 20 for example, the clock signal lines other than that of the clock system 113 may include dummy XOR circuits 231 and/or dummy control signal hold circuits 232, while one of the input nodes of each of the dummy XOR circuits 231 may be grounded instead of providing control signal lines. Also in such a case, the line density can be expected to be reduced by providing no such control signal lines. In addition, the dummy XOR circuits 231 as described above may be used in place of buffers for delay adjustment etc.

The point where a bridging fault is more likely to occur may be predicted considering not only the numbers of the flip-flop circuits 101, but also the numbers of logic circuits and/or devices which are each supplied with a clock.

Sixth Embodiment of Invention

(Method for Determining Installation Locations of XOR Circuits 200 etc.)

Determination of the installation locations of the XOR circuits 200 etc. as described above can be practically performed by a design tool using a computer etc. Here, a design tool for semiconductor devices generally performs, for example, a circuit design step of determining the circuit configuration of circuit elements such as logic circuits and the connection therebetween based on circuit information such as the specification of circuit operations, and a layout design step of determining the arrangement of circuit elements and lines based on the determined circuit configuration. Examples of determining the installation locations of the XOR circuits 200 etc. in the respective steps will be described below.

(Determination of Installation Locations Performed in Circuit Design Step)

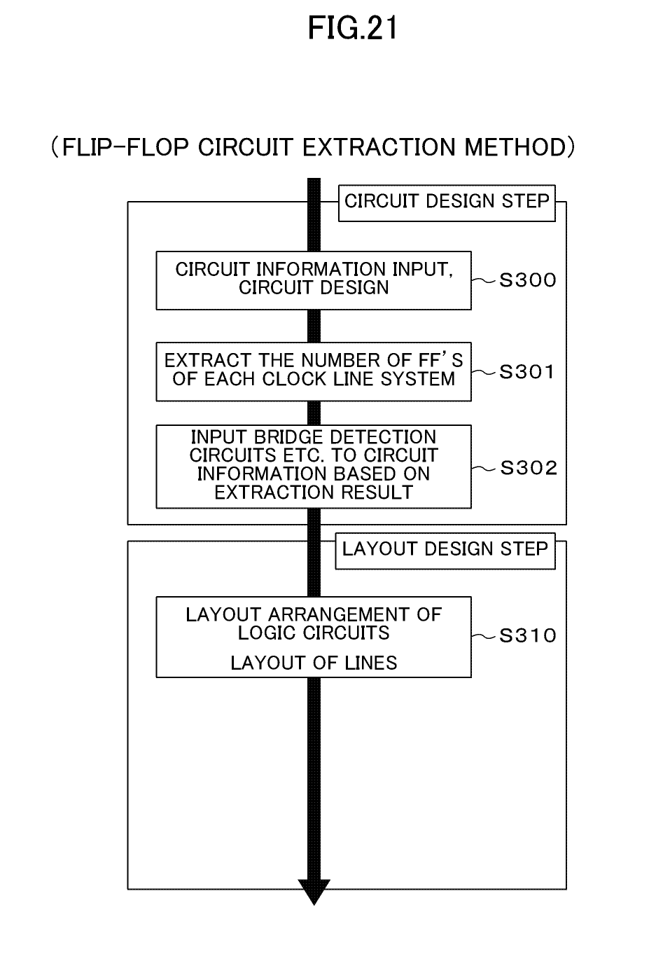

As shown in the flowchart of FIG. 21, the circuit design step can determine the installation locations of the XOR circuits 200 etc., for example, based on the numbers of flip-flop circuits included in the respective clock systems as described above.

(S300) First, circuit information, such as the specification of circuit operations, is input to the design tool, and the circuit configuration, such as circuit elements and the connection therebetween, is determined based on the circuit information. More specifically, for example, circuit design at the RTL level is performed.

(S301) The numbers of flip-flop circuits included in the respective clock systems are obtained.

(S302) A predetermined number of clock systems are selected in descending order of the obtained number of flip-flop circuits included in each clock system, or clock systems including as many flip-flop circuits as a predetermined value or more are selected, and the XOR circuits 200 etc. (e.g., such as those described in the fifth embodiment) corresponding to such clock systems are added to the circuit designed in the above step (S300).

(S310) After this, a layout design step similar to a standard one determines the arrangement of circuit elements and lines including the XOR circuits 200 etc.

(Determination of Installation Locations Performed in Layout Design Step)

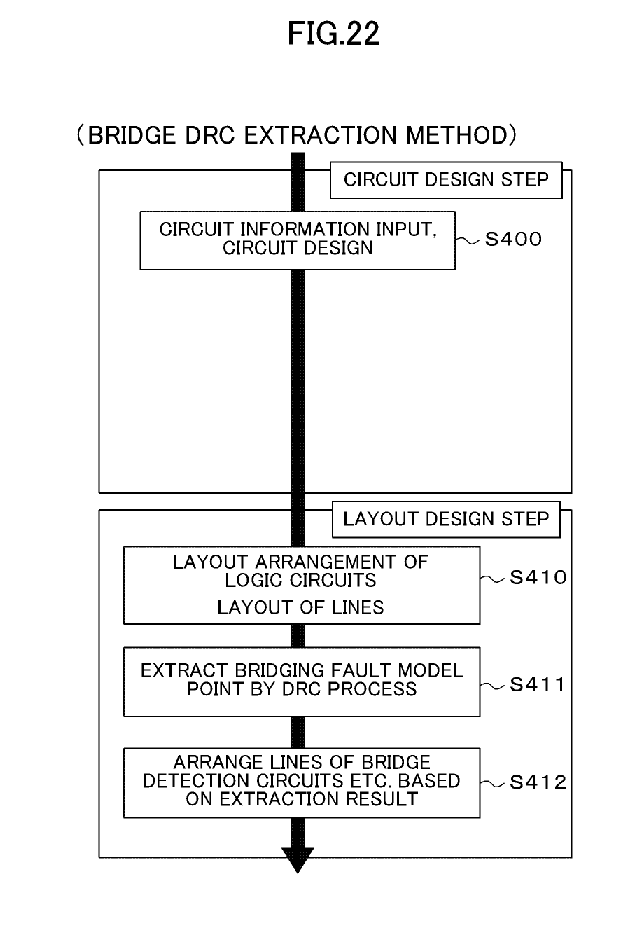

As shown in the flowchart of FIG. 22, the layout design step determines the specific arrangement of the clock signal lines, and accordingly can predict the likelihood of occurrence of a bridging fault with a higher probability based on, for example, the proximity between clock signal lines.

(S400) First, in a similar manner to step 5300 of FIG. 21, circuit information, such as the specification of circuit operations, is input to the design tool, and the circuit configuration, such as circuit elements and the connection therebetween, is determined. Here, if the XOR circuit 200 and the control signal generator 210 etc., including the control signal hold circuit 211, are provided in advance as dummy circuits etc., then adding the line of the control signal 202 between the XOR circuit 200 and the control signal hold circuit 211 of the clock signal line allows a bridging fault to be detectable without a significant layout change after the layout design. More specifically, it is preferable, for example, that the input node for the control signal 202 in the XOR circuit 200 be grounded, or that the output node for the control signal 202 in the control signal hold circuit 211 be open.

The number of such dummy circuits may be less than the number of clock systems. That is, the clock systems each having a high likelihood of occurrence of a bridging fault are often a part of all the clock systems, and thus the number of dummy circuits to be provided may be commensurate with the configuration to reduce the circuit size.

(S410) The arrangement of circuit elements and lines is determined based on the circuit configuration designed at step 5400.

(S411) Next, design rule check (DRC) is performed on the determined arrangement of circuit elements and lines; and in addition to a general examination of whether the physical design criteria are satisfied or not, detection of a point where it is inferred that a bridging fault 103 is highly likely to occur (bridging fault model point) is preformed. Such detection is performed, for example, by setting, in the DRC rules, detection rules on the bridging fault model point, such as rules on intersection points between clock signal lines and on separation between clock signal lines (distance between lines and lengths of lines), and then by checking the arrangement determined at step 5410 based on such rules.

(S412) A line for the control signal 202, on which a bridging fault may actually occur, between the XOR circuit 200 for detecting a bridging fault and the control signal hold circuit 211 is added on the bridging fault model point detected at step 5411. More specifically, as shown in FIG. 20 for example, the XOR circuit 200 and the control signal hold circuit 211 are coupled to the clock signal line which is supplied with the clock signal 104 (or the clock signal 105) during normal operation, corresponding to the bridging fault 103. Meanwhile, the XOR circuits 200 which are not used for detecting the bridging fault are, for example, grounded at the input nodes for the control signals 202. Note that such XOR circuits 200 and such control signal hold circuits 211 may be removed as shown in FIG. 19.

Seventh Embodiment of Invention

The above sixth embodiment has been described assuming that a bridging fault occurs only at one point for simplicity of explanation. However, if bridging faults are highly likely to occur at more than one points, optimization of the location where the XOR circuit 200 is provided allows the circuit size to be reduced.

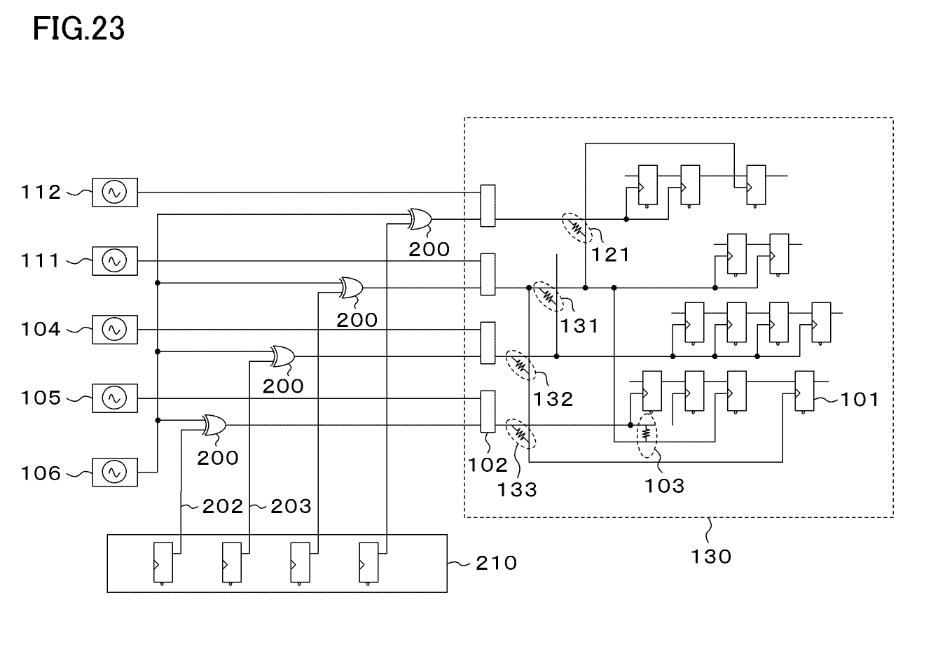

More specifically, as shown in FIG. 23 for example, a case in which five bridging faults 103, 121, 131, 132, and 133 occur will be described.

The bridging faults 103 and 133 both occur between the clock signal lines supplied with the clock signals 111 and 105 during normal operation. Thus, detection of only whether a bridging fault has occurred or not (that is, no differentiation is required between the two bridging faults 103 and 133) requires an examination in which the scan clock signal 106 has a different inversion state only once with respect to the clock signal lines supplied with the clock signals 111 and 105.

Similarly, detection of the bridging fault 131 or 132 only requires an examination in which the scan clock signal 106 has a different inversion state with respect to the clock signal lines supplied with the clock signals 111 and 104.

In addition, the bridging fault 121 is a fault model in which a bridging fault occurs between the clock signal lines supplied with the clock signals 111 and 112. Accordingly, all of the five bridging faults 103, 121, 131, 132, and 133 occur between the clock signal line supplied with the clock signal 111 and another clock signal line. Thus, eventually, an examination in which the scan clock signal 106 has a different inversion state with respect to the clock signal line supplied with the clock signal 111 and the other clock signal line allows the bridging fault to be detected irrespective of which bridging fault occurs. Thus, it is required that the XOR circuit(s) 200 be provided only for the clock signal line corresponding to the clock signal 111 (or all of the clock signal lines but that clock signal line).

As described above, unifying the operations for bridging faults corresponding to a same clock signal line allows the duplicate examinations to be easily removed. Moreover, optimizing the clock signal lines on which the scan clock signal 106 is inverted allows the number of locations where the XOR circuits 200 are provided to be easily reduced.

Eighth Embodiment of Invention

The technique in which only a part of the clock systems include the XOR circuits 200 etc. as described in the sixth and the seventh embodiments described above may be applicable to a process of determining the pattern to drive a plurality of control signals 202 etc. “H” and “L” as described in the second and the third embodiments described above. That is, even when, for example, the XOR circuits 200 etc. are provided for all the clock systems, performing a scan test etc. using a pattern which causes the scan clock signal 106 to have a different inversion state with respect to clock systems on which it is inferred that a bridging fault is highly likely to occur based on the result of the DRC etc. can achieve a high detection probability with a smaller amount of pattern data (i.e., a shorter examination time), without using various exhaustive patterns which cause the scan clock signal 106 to have a different inversion state.

The semiconductor devices according to present invention are advantageous in that a bridging fault can easily be detected which has occurred between clock signal lines which transmit clock signals different from each other during normal operation in semiconductor devices configured such that a scan test can be performed. The present invention relates to semiconductor devices such as scaled complementary metal oxide semiconductor (CMOS) integrated circuits, and more particularly, is useful for semiconductor devices configured such that a scan test can be performed.

What is claimed is:

1. A semiconductor device having a plurality of hold circuits and configured such that a scan test can be performed, comprising:
a first and a second clock signal lines supplied with normal operational clock signals having at least either frequencies or phases different from each other during normal operation; and
a test clock signal controller configured to switch, during a test, between a state in which a first test clock signal, which is the same as that supplied to the first clock signal line, is supplied to the second clock signal line, and a state in which a second test clock signal, which is inverted or phase-shifted relative to the first test clock signal, is supplied to the second clock signal line.

2. The semiconductor device of claim 1, comprising:
a selector configured to select either the normal operational clock signal or the first or the second test clock signal, and to supply a selected signal to the first and the second clock signal lines, wherein
the test clock signal controller is provided in either an input side or an output side of the selector.

3. The semiconductor device of claim 1, wherein
the test clock signal controller includes an exclusive OR circuit, and is configured to receive the first test clock signal at one input node of the exclusive OR circuit, and a switching control signal at the other input node of the exclusive OR circuit.

4. The semiconductor device of claim 1, wherein
the test clock signal controller is used as a delay adjustment device for the normal operational clock signal, the first test clock signal, or the second test clock signal.

5. The semiconductor device of claim 1, comprising:
a plurality of clock signal lines supplied with normal operational clock signals having at least either frequencies or phases different from one another during normal operation, wherein
the test clock signal controller is provided on each of a part of the plurality of clock signal lines.

6. The semiconductor device of claim 1, comprising:
a plurality of clock signal lines supplied with normal operational clock signals having at least either frequencies or phases different from one another during normal operation, wherein
the test clock signal controller provided on each of a part of the plurality of clock signal lines is fixed in the state in which the first test clock signal is supplied.

7. The semiconductor device of claim 1, comprising:
a control signal generator configured to generate a switching control signal which controls a switching status of the test clock signal controller, wherein
the control signal generator includes control signal hold circuits corresponding on a one-to-one basis to multiple ones of the test clock signal controller.

8. The semiconductor device of claim 7, wherein
the control signal generator includes a shift register, and is configured so that data received by the shift register is transferred to the control signal hold circuits.

9. The semiconductor device of claim 7, wherein
the control signal generator includes a counter, and is configured so that data dependent on a number of count clock pulses counted by the counter is transferred to the control signal hold circuits.

10. The semiconductor device of claim 7, wherein
the control signal generator includes a decoder circuit, and is configured so that decoded data obtained by decoding an input signal by the decoder circuit is transferred to the control signal hold circuits.

11. The semiconductor device of claim 7, wherein
the control signal generator includes a random data generator, and is configured so that random data generated by the random data generator is transferred to the control signal hold circuits.

12. The semiconductor device of claim 7, further comprising:
a sequence controller, wherein
the sequence controller is configured to control operation timings of the control signal hold circuits based on a number of pulses of a sequence control clock signal.

13. The semiconductor device of claim 5, wherein
a number of the hold circuits or logic circuits coupled to clock signal lines on which the test clock signal controllers are provided is greater than a number of the hold circuits or logic circuits coupled to clock signal lines on which the test clock signal controllers are not provided.

14. A design method for designing the semiconductor device of claim 13, comprising:
extracting the number of the hold circuits or logic circuits coupled to clock signal lines on which the test clock signal controllers are provided; and
installing the test clock signal controllers on the clock signal lines based on the extracted number of coupled circuits, wherein
the extracting and the installing are performed in a design tool.

15. A design method for designing the semiconductor device of claim 5, comprising:
determining a layout of circuit elements and lines;
predicting a likelihood of occurrence of a bridging fault based on a relative location between clock signal lines arranged based on the layout determined in the determining; and
installing the test clock signal controllers on the clock signal lines based on the prediction, wherein
the determining, the predicting, and the installing are performed in a design tool.

16. The design method for a semiconductor device of claim 15, wherein
the designing is performed on circuits in which the test clock signal controllers are tentatively provided, and
the installing installs the test clock signal controllers by supplying a switching control signal to each of the tentatively provided test clock signal controllers.

17. A design tool for designing the semiconductor device of claim 13, comprising:
an extractor, of the number of coupled circuits, configured to extract the number of the hold circuits or logic circuits coupled to clock signal lines on which the test clock signal controllers are provided; and
an installer, of the test clock signal controllers, configured to install the test clock signal controllers on the clock signal lines based on the extracted number of coupled circuits.

18. A design tool for designing the semiconductor device of claim 5, comprising:
a layout unit configured to determine a layout of circuit elements and lines;
a prediction unit configured to predict a likelihood of occurrence of a bridging fault based on a relative location between clock signal lines arranged based on the layout determined by the layout unit; and
an installer, of the test clock signal controllers, configured to install the test clock signal controllers on the clock signal lines based on the prediction.

19. The design tool for a semiconductor device of claim 18, wherein
the layout unit determines layouts for circuits in which the test clock signal controllers are tentatively provided, and
the installer, of the test clock signal controllers, installs the test clock signal controllers by supplying a switching control signal to each of the tentatively provided test clock signal controllers.

20. A fault detection method for detecting a fault of the semiconductor device of claim 5, comprising:
detecting a bridging fault on the semiconductor device having multiple ones of the test clock signal controller, by setting each of the test clock signal controllers sequentially, one by one, to a switching status of the first or the second test clock signal, whichever is different from that of all the other test clock signal controllers.

21. A fault detection method for detecting a fault of the semiconductor device of claim 5, comprising:
detecting a bridging fault on the semiconductor device having multiple ones of the test clock signal controller, by setting a plurality of test clock signal controllers, which constitute a part of the test clock signal controllers, to a switching status different from that of all the other test clock signal controllers.

22. The fault detection method for a semiconductor device of claim 21, wherein
a test for bridging fault detection for the semiconductor device having multiple ones of the test clock signal controller is performed on a combination of test clock signal controllers having the switching status different from that of all the other test clock signal controllers, wherein the combinations are optimized so that all bridging faults at preset candidate locations of occurrence of bridging faults will be detected, and the number of combinations will be a minimum value.
